(19) United States
(12) Patent Application Publication
(10) Pub. No.: US 2023/0337400 A1
(43) Pub. Date: Oct. 19, 2023

(54) SYSTEM AND METHOD FOR FAN-LESS THERMAL MITIGATION FOR INDUSTRIAL-GRADE APPLIANCES

(71) Applicant: Barracuda Networks, Inc., Campbell, CA (US)

(72) Inventors: Gean Han, San Jose, CA (US); Nicholas Tillman, Morgan Hill, CA (US); Hari Potaraju, San Jose, CA (US)

(21) Appl. No.: 18/098,867

(22) Filed: Jan. 19, 2023

Related U.S. Application Data
(60) Provisional application No. 63/330,558, filed on Apr. 13, 2022.

(51) Int. Cl. H05K 7/20; H05K 1/02

(52) U.S. Cl. CPC H05K 7/205; H05K 1/0203; H05K 7/20127

(57) ABSTRACT

A new approach is proposed to support fan-less thermal mitigation for an industrial-grade appliance. The industrial-grade appliance may comprise a plurality of hardware components that are major sources/regions of heat production in the industrial-grade appliance. Under the proposed approach, a heatsink is included in the industrial-grade appliance to address heat dissipation for all of the major sources/regions of heat production positioned on a main board of the industrial-grade appliance. The heatsink is specifically designed to have a plurality of surfaces that are in contact with all of the major heat-producing components of the industrial-grade appliance, wherein each of the plurality of surfaces of the heatsink has a maximum overlapping surface area with at least one of the major heat-producing components in order to transfer maximum amount of heat through conduction. Under the proposed approach, the heatsink is fan-less wherein no fan is used for heat dissipation.

### CROSS-REFERENCE TO RELATED APPLICATIONS

This application claims the benefit of U.S. Provisional Patent Application No. 63/330,558, filed Apr. 13, 2022, which is incorporated herein in its entirety by reference.

### BACKGROUND

Silicon-based integrated circuits (ICs) such as application-specific integrated circuits (ASICs) can only operate reliably with a certain temperature threshold. For non-limiting examples, complex ASICs such as processors (e.g., central processing units or CPUs) can operate normally at room temperature or under relatively light workload or processing demands. As the processing demands increase, the CPUs emit more heat. If adequate venting or cooling is not provided, the heat trapped in a CPU will create a heating cycle, leading to failure of the CPU within minutes.

Currently, mechanical solutions, e.g., mounting cooling fans and airflow channels, are often used to cool the CPUs and other components in most computing devices such as desktop and laptop computers and to release heat emitted and generated by the CPUs. Such mechanical solutions, however, may not be optimal for industrial-grade appliances that each includes multiple electronic circuitries, hardware components, memories, and processors and are often deployed in harsh industrial (vs. relatively-shielded office/indoor) environments where the industrial-grade appliances may experience wide ranges of vibration, noise, and temperature changes (e.g., −20 degrees to 70 degrees) during their deployment. As a result of such harsh industrial environments, the mechanical solutions for cooling these industrial-grade appliances may get rattled or loosened during shipping and are heavily prone to wear and tear. A more reliable cooling solution for the industrial-grade appliances is desired.

The foregoing examples of the related art and limitations related therewith are intended to be illustrative and not exclusive. Other limitations of the related art will become apparent upon a reading of the specification and a study of the drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example of a system diagram to support thermal mitigation for an industrial-grade appliance in accordance with some embodiments.

FIG. 2 depicts an example of a heatsink used for thermal mitigation for an industrial-grade appliance in accordance with some embodiments.

FIG. 3 depicts views from different viewpoints of the example of the heatsink in FIG. 2 in accordance with some embodiments.

FIG. 4 depicts an example of a schematic diagram of a main board of the industrial-grade appliance having a heatsink and various heat-producing components in accordance with some embodiments.

FIG. 5 depicts views from different viewpoints of an example of the main board having the heatsink and the various heat-producing components of the industrial-grade appliance in accordance with some embodiments.

FIG. 6 depicts a picture of an example of the main board having a heatsink with fins in accordance with some embodiments.

FIG. 7 depicts an example of the industrial-grade appliance having a chassis with multiple vents and one or more ribbed sides in accordance with some embodiments.

FIG. 8 depicts an example of upward airflow through vents on the chassis of the industrial-grade appliance for heat dissipation in accordance with some embodiments.

FIG. 9 depicts a flowchart of an example of a process to support thermal mitigation for an industrial-grade appliance in accordance with some embodiments.

### DESCRIPTION

The following disclosure provides many different embodiments, or examples, for implementing different features of the subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

A new approach is proposed that contemplates systems and methods to support fan-less thermal mitigation for an industrial-grade appliance. Here, the industrial-grade appliance may comprise a plurality of hardware components that are major sources/regions of heat production in the industrial-grade appliance. Under the proposed approach, a heatsink is included in the industrial-grade appliance to address heat dissipation for all of the major sources/regions of heat production positioned on a main board of the industrial-grade appliance. In some embodiments, the heatsink is specifically designed to have a plurality of surfaces that are in contact with all of the major heat-producing components of the industrial-grade appliance, wherein each of the plurality of surfaces of the heatsink has a maximum overlapping surface area with at least one of the major heat-producing components in order to transfer the maximum amount of heat through conduction.

Under the proposed approach, the heatsink is fan-less wherein no fan is used or needed by the heatsink for heat dissipation or conduction. Specifically, the plurality of surfaces of the heatsink are designed and positioned to be in close contact with the major heat-producing components of the industrial-grade appliance, e.g., a CPU, a memory module and/or a network processor, in order to dissipate heat from these heat-producing components efficiently and simultaneously. In addition, the heatsink is configured to artificially induce airflow through the industrial-grade appliance by deliberately creating a vertical cross-ventilation path and orienting the major heat-producing components against the ventilation path via fins.

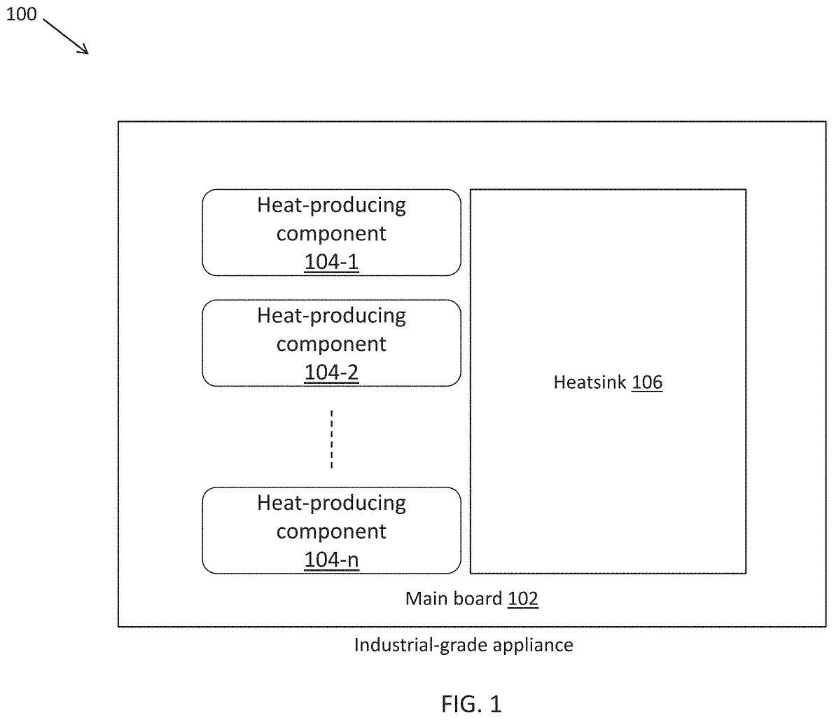

FIG. 1 depicts an example of a system diagram to support fan-less thermal mitigation for an industrial-grade appliance. Although the diagrams depict components as functionally separate, such depiction is merely for illustrative purposes. It will be apparent that the components portrayed in this figure can be arbitrarily combined or divided into separate software, firmware and/or hardware components. Furthermore, it will also be apparent that such components, regardless of how they are combined or divided, can execute on the same host or multiple hosts, wherein the multiple hosts can be connected by one or more networks.

In the example of FIG. 1, the industrial-grade appliance 100 includes a main board 102 having a plurality of heat-producing components 104s and a fan-less heatsink 106 that is in close proximity and/or direct contact with the plurality of heat-producing components 104s. As discussed herein, the plurality of heat-producing components 104s are major sources/regions of heat production in the industrial-grade appliance 100, wherein each of the plurality of heat-producing components 104s can be but are not limited to, a single-core or multi-core processor, e.g., Marvell Armada 88F3720 dual-core processor, which is a CPU residing on the main board 102 of the industrial-grade appliance 100, a network processor, e.g., Marvell 88E6341 network processor, which attaches to the main board 102 and, in some embodiments, also connects to a daughter board with Power over Ethernet (PoE) circuitry having a transformer that produces heat, and one or more memory modules soldered into the main board 102 of the industrial-grade appliance 100.

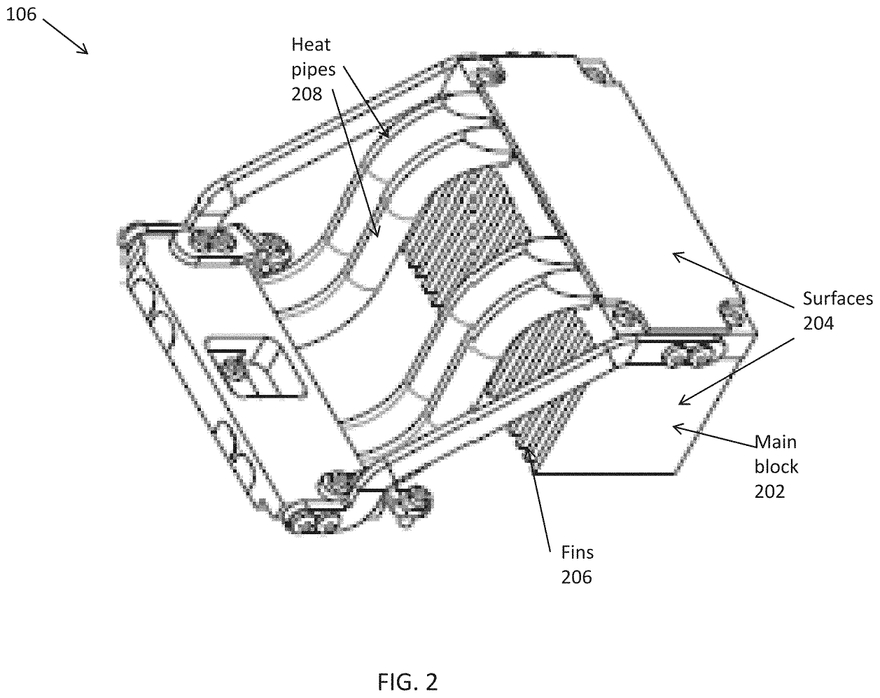

FIG. 2 depicts an example of the heatsink 106 used for thermal mitigation for the industrial-grade appliance 102. As shown by the example of FIG. 2, the heatsink 102 has a main (cooling) block 202 configured to dissipate and/or absorb heat generated by the plurality of heat-producing components 104s that are in direct contact with one or more surfaces 204s of the main block 202 through conduction. In some embodiments, each of a plurality of the surfaces 204s of the main block 202 has a maximum overlapping surface area with an area of a surface of at last one of the plurality of heat-producing components 104s to transfer the maximum amount of heat through conduction. In some embodiments, a thermal paste (not shown) resides between the main block 202 of the heatsink 106 and the heat-producing components 104s to facilitate heat dissipation.

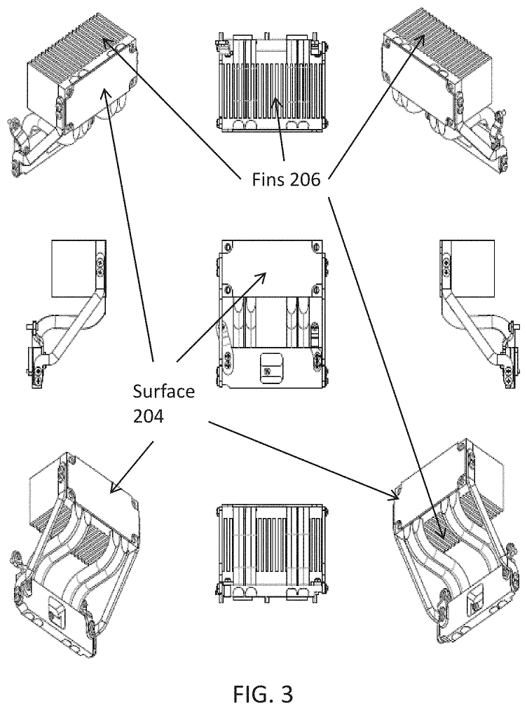

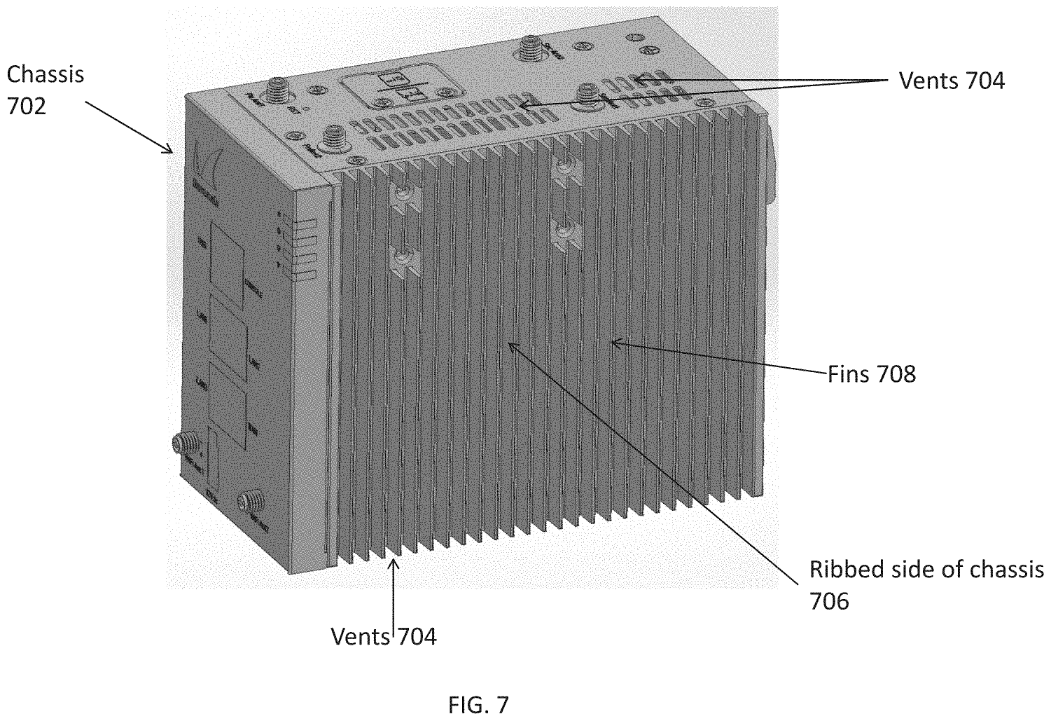

In some embodiments, the main block 202 further includes one or more arrays/sets of fins 206 configured to direct heat generated by the plurality of heat-producing components 104s that are in close contact with heatsink 106 through an upward airflow in a certain direction, allowing for further dissipation of heat directly through the vents 704 on a top surface of a chassis of the industrial-grade appliance 102 by convection. FIG. 3 depicts a set of views of the example of the heatsink 106 depicted in FIG. 2 with the one or more surfaces 204s and the sets of fins 206s shown from a plurality of different viewpoints. In some embodiments, at least one of the one or more surfaces 204 of the main block 202 is attached to a ribbed side of the chassis 702 of the industrial-grade appliance 102 for heat dissipation as shown in FIG. 7. In some embodiments, the heatsink 106 further includes a plurality of heat (cooling) pipes 208 configured to direct and dissipate heat generated by the plurality of heat-producing components 104s out of the industrial-grade appliance 102. In some embodiments, the plurality of heat pipes 208 are made of copper. In some embodiments, the plurality of heat pipes 208 are attached or connected to the one or more surfaces 204 of the main block 202 of the heatsink 106. Such direct contact, facilitated by high-quality thermal paste that allows for efficient transfer of heat to the plurality of heat pipes 208, carries the heat further upwards to the main block 202 of the heatsink 106. In some embodiments, the heat is dissipated via conduction to the ribbed side of the chassis of the industrial-grade appliance 102 as well as convection via the vents at the top and/or bottom of the chassis as shown in FIG. 7.

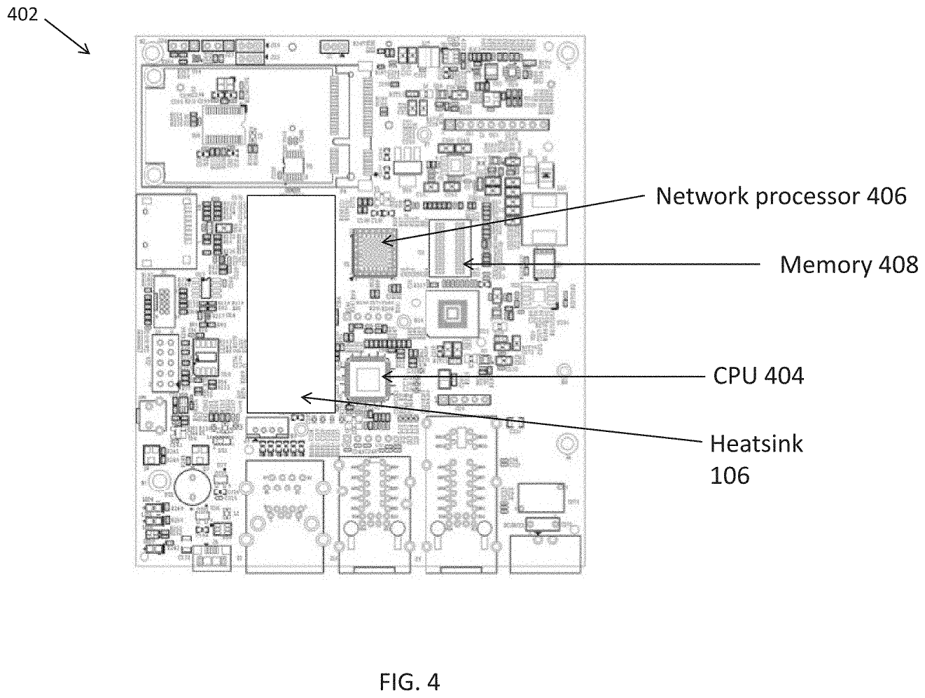

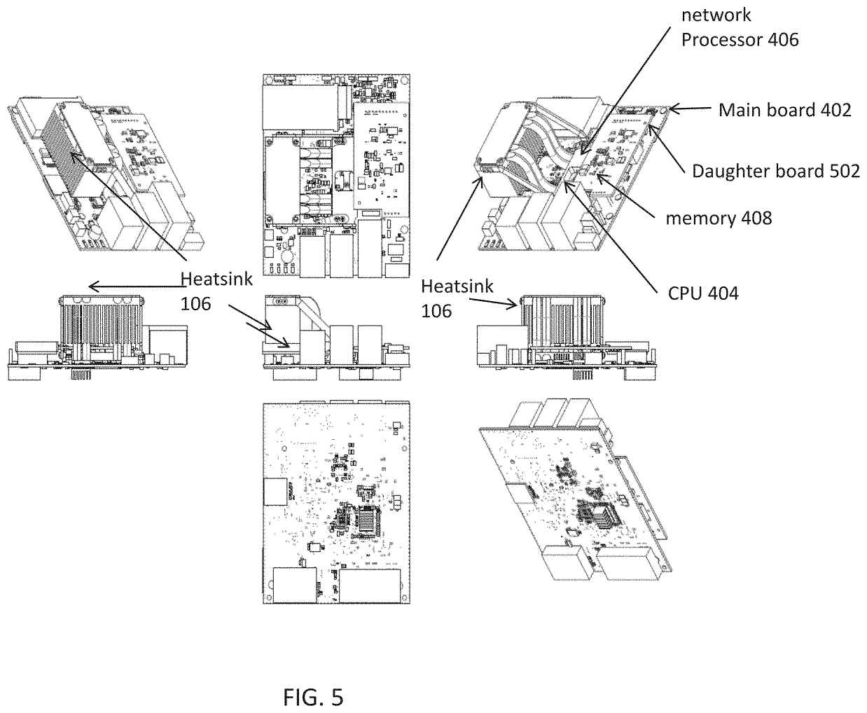

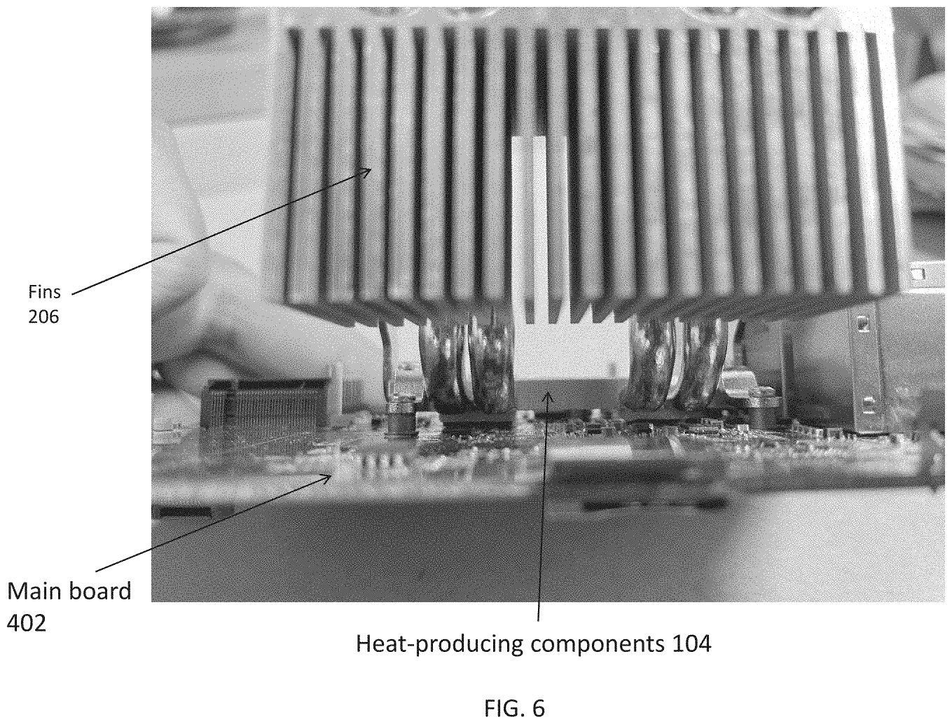

FIG. 4 depicts an example of a schematic diagram of a main board 402 of the industrial-grade appliance 102. Here, the main board 402 includes a plurality of heat-producing components 104s that are main sources/regions of heat production on the industrial-grade appliance 102. As shown by the example of FIG. 4, the plurality of heat-producing components 104s include but are not limited to a CPU 404, network processor 406, and a memory module 408. The heatsink 106 is also included on the main board 402 and is positioned in close proximity to/contact with the CPU 404, the network processor 406, and the memory module 408 as well as other heat-generating components on the main board 402 of the industrial-grade appliance 102. FIG. 5 depicts views of an example of the main board 402 having the heatsink 106 and the various heat-producing components 104s of the industrial-grade appliance from a plurality of different viewpoints. In some embodiments, the industrial-grade appliance 102 may further include a daughter board 502 on top of the main board 402 and is in close proximity or direct contact with the heatsink 106, wherein the PoE circuitry of the daughter board 502 is a main source of heat production. As shown by the example of FIG. 5, in some embodiments, the CPU 404 on the main board 402 is placed behind the daughter board 502 while the network processor 406 and the memory module 408 on the main board 402 may be placed under the daughter board 502. FIG. 6 depicts a picture of an example of the main board 402 having a plurality of heat-producing components 104s and a heatsink with a set of fins 206 above the plurality of heat-producing components 104s to direct and dissipate heat generated by the plurality of heat-producing components 104s. In some embodiments, the set of fins is further oriented to leverage the upward airflow to dissipate heat via convection.

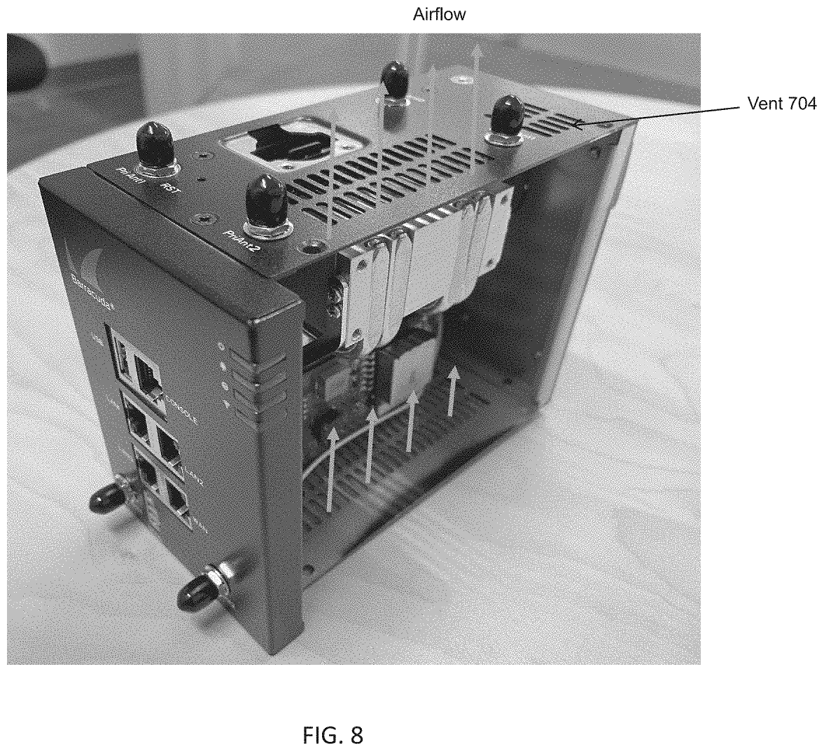

In some embodiments, the industrial-grade appliance 102, the plurality of heat-producing components 104s, and the heatsink 106 on its main board 402 or daughter board 502 are shielded and contained in a chassis 702. FIG. 7 depicts an example of the industrial-grade appliance 102 shielded and contained in the chassis 702. In some embodiments, the chassis 702 has one or more ribbed sides 706s and/or one or more sets of vents (ventilation holes) 704s on the top and/or bottom side of the chassis 702, wherein the one or more sets of vents 704s and/or the one or more ribbed sides 706s are configured to direct/induce a fan-less upward airflow to dissipate heat from the plurality of heat-producing components 104s of the industrial-grade appliance 102 out of the chassis 702 as shown by the example of FIG. 8. In some embodiments, the plurality of heat pipes 208 are configured to interconnect the plurality of heat-generating components 104s to the one or more set of fins 206 and to break out to connect to a lateral side of the chassis 702, thereby facilitating heat dissipation via conduction as well as convection simultaneously. In some embodiments, one of the lateral sides of the chassis 702 is ribbed with a set of fins 708, which turns one entire side surface of the chassis 702 into a giant heatsink. Such heat dissipating arrangement allows for efficient heat transfer all the way up the plurality of heat pipes 208 to the main block 202 of the heatsink 106 as shown in FIG. 2. In some embodiments, the main block 202 of the heatsink 106 is connected to one of the one or more ribbed sides 706 of the chassis 702, which in turn acts as an external heatsink to allow for heat to dissipate out of the industrial-grade appliance into the surrounding air.

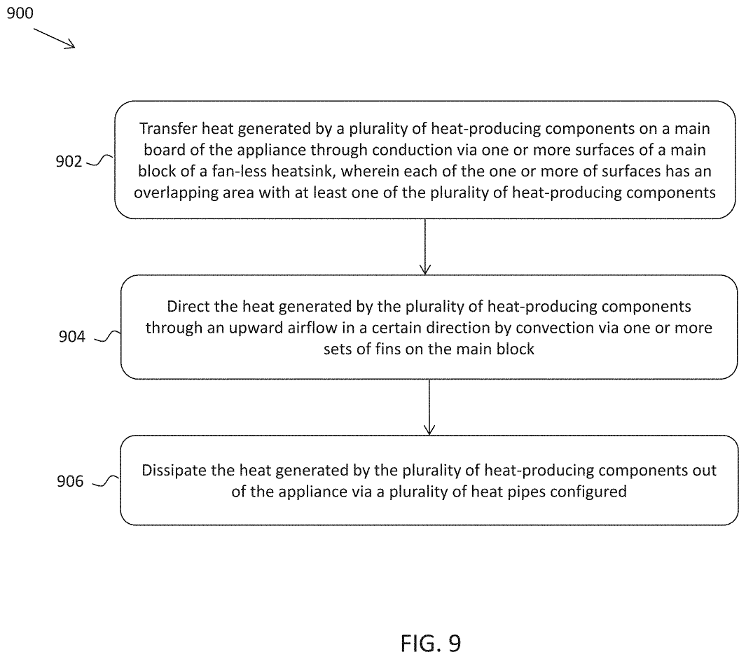

FIG. 9 depicts a flowchart 900 of an example of a process to support thermal mitigation for an industrial-grade appliance. Although the figure depicts functional steps in a particular order for purposes of illustration, the processes are not limited to any particular order or arrangement of steps. One skilled in the relevant art will appreciate that the various steps portrayed in this figure could be omitted, rearranged, combined, and/or adapted in various ways.

In the example of FIG. 9, the flowchart 900 starts at block 902, where heat generated by a plurality of heat-producing components on a main board of the appliance is transferred via conduction via one or more surfaces of a main block of a fan-less heatsink, wherein each of the one or more of surfaces has an overlapping area with at least one of the plurality of heat-producing components. The flowchart 900 continues to block 904, where the heat generated by the plurality of heat-producing components is directed through an upward airflow in a certain direction by convection via one or more sets of fins on the main block. The flowchart 900 ends at block 906, where the heat generated by the plurality of heat-producing components is directed and dissipated out of the appliance via a plurality of heat pipes configured.

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Embodiments were chosen and described in order to best describe the principles of the invention and its practical application, thereby enabling others skilled in the relevant art to understand the claimed subject matter, the various embodiments and the various modifications that are suited to the particular use contemplated.

What is claimed is:

1. A system to support fan-less thermal mitigation of an appliance, comprising:
a fan-less heatsink including
a main block having one or more surfaces, wherein each of the one or more surfaces has an overlapping area with at least one of a plurality of heat-producing components on a main board of the appliance to transfer heat generated by the plurality of heat-producing components through conduction;
one or more sets of fins on the main block, wherein the one or more sets of fins are configured to direct the heat generated by the plurality of heat-producing components through an upward airflow in a certain direction by convection;
a plurality of heat pipes configured to dissipate the heat generated by the plurality of heat-producing components out of the appliance.

2. The system of claim 1, wherein:
each of the plurality of heat-producing components of the appliance is one of a CPU, a network processor, and a memory module.

3. The system of claim 1, wherein:
the plurality of heat pipes are made of copper.

4. The system of claim 1, wherein:
the plurality of heat pipes are connected to the one or more surfaces of the main block to transfer heat further upwards to the main block of the heatsink.

5. The system of claim 1, wherein:
the heat sink is positioned in close proximity or direct contact with a daughter board on top of the main board, wherein circuitry of the daughter board is a main source of heat production.

6. The system of claim 5, wherein:
one or more of the plurality of heat-producing components of the appliance, the heatsink, and the daughter board are shielded and contained in a chassis.

7. The system of claim 6, wherein:
the chassis has one or more ribbed sides and/or one or more sets of vents on a top and/or a bottom side of the chassis, wherein the one or more ribbed sides and/or the one or more sets of vents are configured to direct the upward airflow to dissipate heat from the plurality of heat-producing components out of the chassis of the appliance via convection.

8. The system of claim 7, wherein:
at least one of the one or more surfaces of the main block is attached to one of the one or more ribbed sides of the chassis of the appliance for heat dissipation.

9. The system of claim 7, wherein:
the plurality of heat pipes are configured to interconnect the plurality of heat-generating components to the one or more set of fins and to break out to connect to one of the one or more ribbed sides of the chassis thereby facilitating heat dissipation via conduction as well as convection simultaneously.

10. The system of claim 7, wherein:
one of the one or more ribbed sides of the chassis has a set of fins, which enables heat transfer all the way up the plurality of heat pipes to the main block of the heatsink.

11. The system of claim 7, wherein:
the main block of the heatsink is connected to one of the one or more ribbed sides of the chassis, which in turn acts as an external heatsink to allow for heat to dissipate into the surrounding air.

12. A method to support fan-less thermal mitigation of an appliance, comprising:
transferring heat generated by a plurality of heat-producing components on a main board of the appliance through conduction via one or more surfaces of a main block of a fan-less heatsink, wherein each of the one or more surfaces has an overlapping area with at least one of the plurality of heat-producing components;
directing the heat generated by the plurality of heat-producing components through an upward airflow in a certain direction by convection via one or more sets of fins on the main block;
dissipating the heat generated by the plurality of heat-producing components out of the appliance via a plurality of heat pipes.

13. The method of claim 12, further comprising:
positioning the heat sink in close proximity or direct contact with a daughter board on top of the main board, wherein circuitry of the daughter board is a main source of heat production.

14. The method of claim 13, further comprising:
shielding and containing one or more of the plurality of heat-producing components of the appliance, the heatsink, and the daughter board in a chassis.

15. The method of claim 14, further comprising:
directing the upward airflow to dissipate heat from the plurality of heat-producing components out of the chassis of the appliance via convection via one or more ribbed sides and/or one or more sets of vents on a top and/or a bottom side of the chassis.

16. The method of claim 14, further comprising:
attaching at least one of the one or more surfaces of the main block to one of the one or more ribbed sides of the chassis of the appliance for heat dissipation.

17. The method of claim 14, further comprising:
interconnecting the plurality of heat-generating components to the one or more sets of fins via the plurality of heat pipes, which break out to connect to one of the one or more ribbed sides of the chassis thereby facilitating heat dissipation via conduction as well as convection simultaneously.

18. The method of claim 14, further comprising:
enabling heat transfer all the way up the plurality of heat pipes to the main block of the heatsink via a set of fins on one of the one or more ribbed sides of the chassis.

19. The method of claim 14, further comprising:
connecting the main block of the heatsink to one of the one or more ribbed sides of the chassis, which in turn acts as an external heatsink to allow for heat to dissipate into the surrounding air.

20. A system to support fan-less thermal mitigation of an appliance, comprising:
a fan-less heatsink including
a means having one or more surfaces, wherein each of the one or more surfaces has an overlapping area with at least one of a plurality of heat-producing components on a main board of the appliance to transfer heat generated by the plurality of heat-producing components through conduction;
a means for directing the heat generated by the plurality of heat-producing components through an upward airflow in a certain direction by convection;
a means for dissipating the heat generated by the plurality of heat-producing components out of the appliance.
